(19) United States
(12) Patent Application Publication
(10) Pub. No.: US 2020/0006501 A1
(43) Pub. Date: Jan. 2, 2020

(54) DIELECTRIC LINING LAYERS FOR SEMICONDUCTOR DEVICES

(71) Applicant: Intel Corporation, Santa Clara, CA (US)

(72) Inventors: Willy Rachmady, Beaverton, OR (US); Sean T. Ma, Portland, OR (US); Matthew V. Metz, Portland, OR (US); Nicholas G. Minutillo, Beaverton, OR (US); Cheng-Ying Huang, Hillsboro, OR (US); Dewey Gilbert, Hillsboro, OR (US); Jack T. Kavalieros, Portland, OR (US); Anand S. Murthy, Portland, OR (US); Tahir Ghani, Portland, OR (US)

(73) Assignee: Intel Corporation, Santa Clara, CA (US)

(21) Appl. No.: 16/490,504

(22) PCT Filed: Mar. 31, 2017
(86) PCT No.: PCT/US2017/025447

§ 371 Date: Aug. 30, 2019

(51) Int. Cl. H01L 29/40; H01L 27/092; H01L 29/78; H01L 29/10; H01L 29/66; H01L 21/8252

(52) U.S. Cl. CPC H01L 29/408; H01L 27/092; H01L 29/78; H01L 29/20; H01L 29/6656; H01L 29/66545; H01L 21/8252; H01L 29/1033

(57) ABSTRACT

Solid-state assemblies including dielectric lining layers having localized charges are provided. Processes to form the solid-state assemblies also are provided. The solid-state assemblies can included in CMOS transistors, where first dielectric lining layers having localized charges of positive polarity can be adjacent to the PMOS member and a second dielectric lining layers having localized charges of positive polarity can be adjacent to an NMOS member. The first dielectric lining layers can be adjacent to a first gate electrode of the CMOS transistor, and the second dielectric lining can be adjacent to a second gate electrode of the CMOS transistor. The first dielectric lining layers and the second dielectric lining layers can improve, at least in part, the performance of the CMOS transistor by attracting mobile carriers into respective transport channels of the PMOS member and the NMOS member.

### BACKGROUND

Miniaturization of solid-state transistors includes the reduction of gate length in order to increase performance and layout density. Yet, a shorter gate length in a solid-state transistor usually results in a more robust short channel effect, with the ensuing increase in current leakage. Therefore, much remains to be improved in the reduction of parasitic capacitance in miniaturized solid-state transistors.

### BRIEF DESCRIPTION OF THE DRAWINGS

The accompanying drawings are an integral part of the disclosure and are incorporated into the subject specification. The drawings illustrate example embodiments of the disclosure and, in conjunction with the description and claims, serve to explain at least in part various principles, features, or aspects of the disclosure. Certain embodiments of the disclosure are described more fully below with reference to the accompanying drawings. However, various aspects of the disclosure can be implemented in many different forms and should not be construed as limited to the implementations set forth herein. Like numbers refer to like, but not necessarily the same or identical, elements throughout.

FIG. 1 presents a schematic cross-sectional view of an example solid-state assembly in accordance with one or more embodiments of the disclosure.

FIG. 2 illustrates a schematic cross-sectional view of an example solid structure representative of a stage of an example process for fabricating a CMOS transistor or another type of semiconductor device, in accordance with one or more embodiments of the disclosure.

FIG. 3 illustrates a schematic cross-sectional view of another example solid-state assembly representative of another stage of the example process for fabricating the CMOS transistor or other type of semiconductor device, in accordance with one or more embodiments of the disclosure.

FIG. 4 illustrates a schematic cross-sectional view of another example solid-state assembly representative of another stage of the example process for fabricating the CMOS transistor or other type of semiconductor device, in accordance with one or more embodiments of the disclosure.

FIG. 5 illustrates a schematic cross-sectional view of another example solid-state assembly representative of another stage of the example process for fabricating the CMOS transistor or other type of semiconductor device, in accordance with one or more embodiments of the disclosure.

FIG. 6 illustrates a schematic cross-sectional view of another example solid-state assembly representative of another stage of the example process for fabricating the CMOS transistor or other type of semiconductor device, in accordance with one or more embodiments of the disclosure.

FIG. 7 illustrates a schematic cross-sectional view of another example solid-state assembly representative of another stage of the example process for fabricating the CMOS transistor or other type of semiconductor device, in accordance with one or more embodiments of the disclosure.

FIG. 8 illustrates a schematic cross-sectional view of another example solid-state assembly representative of another stage of the example process for fabricating the CMOS transistor or other type of semiconductor device, in accordance with one or more embodiments of the disclosure.

FIG. 9 illustrates a schematic cross-sectional view of another example solid-state assembly representative of another stage of the example process for fabricating the CMOS transistor or other type of semiconductor device, in accordance with one or more embodiments of the disclosure.

FIG. 10 illustrates a schematic cross-sectional view of another example solid-state assembly representative of another stage of the example process for fabricating the CMOS transistor or other type of semiconductor device, in accordance with one or more embodiments of the disclosure.

FIG. 11 illustrates a schematic cross-sectional view of another example solid-state assembly representative of another stage of the example process for fabricating the CMOS transistor or other type of semiconductor device, in accordance with one or more embodiments of the disclosure.

FIG. 12 illustrates a schematic cross-sectional view of another example solid-state assembly representative of another stage of the example process for fabricating the CMOS transistor or other type of semiconductor device, in accordance with one or more embodiments of the disclosure.

FIG. 13 illustrates an example of a method of fabricating solid-state devices in accordance with one or more embodiments of the disclosure.

FIG. 14 presents an example of a system that utilizes solid-state devices in accordance with one or more embodiments of the disclosure.

### DETAILED DESCRIPTION

The disclosure recognizes and addresses, in at least some embodiments, the issue of scaling complementary metal-oxide-semiconductor (CMOS) devices without compromising performance. As described in greater detail below, embodiments of the disclosure provide solid-state assemblies that can constitute CMOS transistors, and processes to fabricate such solid-state assemblies. In contrast to conventional CMOS transistors, the solid-state assemblies do not leverage transport electrode extensions (e.g., a source electrode extension or a drain electrode extension) under a gate electrode of a CMOS transistor. Instead, in some embodiments, the solid-state assemblies can include dielectric lining layers, each containing localized charges of a defined polarity. Such spacer liners can permit reducing leakage floor and maintaining high drive current in a CMOS transistor, without reliance on gate underlaps. In some embodiments, in a CMOS transistors, an n-type metal-oxide-semiconductor (NMOS) component and a p-type metal-oxide-semiconductor (PMOS) component can be assembled with respective dielectric lining materials having localized charges of different polarities due to the type of different mobile carriers in a transport channel of the NMOS component and PMOS component. Specifically, a dielectric lining layer having localized charged of a polarity that is opposite to the other polarity of mobile carriers in the transport channel can improve performance by attracting mobile carriers to the channel from a source contact. In some embodiments, positive localized charges, such as those found in Al₂O₃, can improve performance of an NMOS portion of the CMOS transistor. In addition or in other embodiments, negative localized charges, such as those in non-stoichiometric La2O3, can improve performance of a PMOS portion of the CMOS transistor.

Solid-state assemblies in accordance with aspects of this disclosure can be implemented in MOS transistors with high mobility channel materials, such as Ge and III-V semiconductor compounds. In contrast to conventional transistors, the solid-state assemblies can mitigate or otherwise remove gate-induced drain-leakage (GIDL) and/or BIBL despite the low energy bandgap of such channel materials, without reliance on electrode tips (e.g., source contact extensions or drain contact extensions) under a gate electrode.

Embodiments of the disclosure can provide various advantages over conventional CMOS transistors. In one example advantage, a CMOS transistor or another type of semiconductor device that utilizes dielectric liners in accordance with aspects of this disclosure can improve performance without reliance of doping the dielectric liners. For instance, a dielectric lining layer having a 10¹³ cm⁻² density of localized charges can provide similar reduction in leakage floor, while maintaining current drive, than a conventional CMOS having a doped extension tip having a dopant concentration of about 5·10¹⁹ cm⁻².

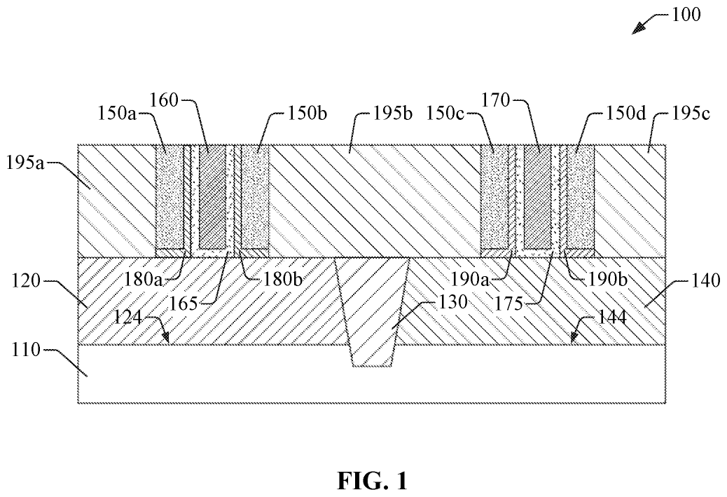

With reference to the drawings, FIG. 1 illustrates a schematic cross-sectional view of a solid-state assembly 100 that can embody or can constitute a CMOS transistor or another type of solid-state device, in accordance with one or more embodiments of the disclosure. As mentioned, in some embodiments, the CMOS transistor or the solid-state device can embody or can constitute a planar FET, non-planar FET, such as a FinFET, all-around-gate FETs, tri-gate FETs, dual-gate FETs, or other types of non-planar FETs having contact members (e.g., a source contact member and/or a drain contact member) embodied in one or more nanowires.

The solid-state assembly 100 includes a semiconductor substrate 110 that can be formed from or can include a carrier-doped semiconductor material (e.g., p-type semiconductor material) or an intrinsic semiconductor material. The semiconductor substrate 110 can be embodied in or can include a Si substrate, an InAs substrate, a GaAs substrate, an InP substrate, or another type of substrate formed from a semiconductor material having a high energy bandgap (e.g., an energy bandgap in a range from about 0.5 eV to about 2 eV). Such a semiconductor material can be selected from a group of materials including a SiₓₓGe_{y}, III-V compounds, II-VI compounds, a combination thereof, or the like. The indices x, and y are real numbers indicative of a defined stoichiometry of a compound.

The solid-state assembly 100 also includes a PMOS member 120 and an NMOS member 140 separated from each other by an isolation member 130 (such as a shallow trench isolation (STI) layer). As illustrated, the isolation member 130 can be partially embedded in the semiconductor substrate 110, and forms a first interface with the PMOS member 120 and a second interface with the NMOS member 140. The PMOS member 120 be embodied in or can include a slab of a first semiconductor material doped n-type, and can include two non-contiguous regions of semiconductor material doped p-type or p+-type. In some embodiments, the first semiconductor material can be embodied in Ge or a III-V semiconductor compound (e.g., InAs, GaAs, InₓGa_{y}As, InP, GaP, InₓAl_{y}As, GaₓAl_{y}As, InSb, GaAsₓSb_{y}, InₓAl_{y}Sb_{z}, InAsₓSb_{y}, InₓGa_{y}As_{z}P_{1-z}, or the like) having an energy bandgap less than the energy bandgap of the material that forms the semiconductor substrate 110. The indices x and y are real numbers indicative of a defined stoichiometry of a compound. In some embodiments, the InₓGa_{y}As alloy can have x in a range from about 0.2 to about 0.99, with y=1−x.

The NMOS member 140 be embodied in or can include a slab of a second semiconductor material doped p-type, and also can include two non-contiguous regions of semiconductor material doped n-type or n+-type. In some embodiments, the second semiconductor material can be embodied in Ge or a III-V semiconductor compound having an energy bandgap less than the energy bandgap of the material that forms the semiconductor substrate 110. In some embodiments, the second semiconductor material can be essentially the same as the first semiconductor material—e.g., both such materials can be embodied in Ge, InSb, or nominally the same InGaAs compound, InAlAs compound, or InAlSb compound. In other embodiments, the second semiconductor material and the first semiconductor material can be different.

The solid-state assembly 100 also can include a first gate electrode member 160 and a second gate electrode member 170. In some embodiments, the first gate electrode member 160 can be embodied in or can include, for example, a conductive material, such as polysilicon, a metal, a conductive ceramic (e.g., carbides, such as ZrC or TiC, or nitrides, such as TiN or TaN), a conductive polymer, or the like. The metal can include for example, one or more of copper, aluminum, tungsten, titanium, tantalum, silver, gold, palladium, platinum, zinc, nickel, or an alloy of two or more of the foregoing metals. In addition or in other embodiments, the second gate electrode member 170 can be embodied in or can include, for example, a conductive material, such as polysilicon, a metal, a conductive ceramic, a conductive polymer, or the like. The metal can include, for example, one or more of copper, aluminum, tungsten, titanium, tantalum, silver, gold, palladium, platinum, zinc, nickel, or an alloy of two or more of the foregoing metals.

In addition, a first dielectric layer 165 and a second dielectric layer 175 can coat or otherwise cover, respectively, a portion of the first gate electrode member 160 and another portion of the second gate electrode member 170. As such, in one aspect, the first dielectric layer 165 can separate the first gate dielectric member 160 from other elements of the solid-state assembly 100. Similarly, in another aspect, the second dielectric layer 175 can separate the second gate dielectric member 170 from yet other elements of the solid-state assembly 100. Each of the first dielectric layer 160 and the second dielectric layer 170 can serve as a gate dielectric and can be formed from or can include a high-K dielectric material. In some embodiments, the high-K dielectric material can include, for example, alumina; silicon monoxide (SiO, K of about 5.0); silicon dioxide (SiO₂, K of about 3.9); titanium dioxide; silicon nitride (SiO₃N₄, K of about 6); boron nitride (BN, K of about 4.5); alkali halides (such as rubidium bromide (RbBr, K of about 4.7), lithium fluoride (LiF, K of about 9.2), barium titanate (BaTiO₃, K varies from about 130 to about 1000), lead titanate (PbTiO₃, K ranges between about 200 to about 400); and metal oxides (e.g., hafnium dioxide (HfO₂, K of about 40), tantalum oxide (TaO₅ K of about 27), tungsten oxide (WO₃, K of about 42) and zirconium dioxide (ZrO₂, K of about 24.7). In other embodiments, the high-K material can include, for example, La₂O₃, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiN, a silicate thereof, or an alloy thereof. In some embodiments, each of the first dielectric layer 160 and the second dielectric layer 170 can have a substantially uniform thickness having a magnitude in a range from about 1 nm to about 5 nm.

The solid-state assembly 100 also can include a first spacer layer 150a, a second spacer layer 150b, a third spacer layer 150c, and a fourth spacer layer 150d. The first spacer layer 150a and the second spacer layer 150b can be adjacent to the gate electrode member 160. The third spacer layer 150c and the fourth spacer layer 150d can be adjacent to the gate electrode member 170. In some embodiments, each of the first spacer layer 150a, the second spacer layer 150b, the third spacer layer 150c, and the fourth spacer layer 150d can have a substantially uniform thickness t having a magnitude within the range from about 2 nm to about 10 nm. In addition, each of the first spacer layer 150a, a second spacer layer 150b, a third spacer layer 150c, and a fourth spacer layer 150d can be formed from or can include a low-K dielectric material, such as an oxide (such as a carbon doped oxide or a fluorine doped oxide); a nitride (such as carbon doped silicon nitride or a halogen doped nitride); a carbide; a silicate (such as an organo silicate glass); diamond like carbon (DLC); fluorinated DLC; parylene-N; parylene-F; a combination thereof (e.g., multiple layers of different materials), or the like.

The solid-state assembly also can include a first dielectric layer 180a and a second dielectric layer 180b adjacent to the PMOS member 120, and a third dielectric layer 190a and a fourth dielectric layer 190b adjacent to NMOS member 140. Specifically, the first dielectric layer 180 and the second dielectric layer 180b for respective first interfaces with the PMOS member 120. In addition, the third dielectric layer 190a and the fourth dielectric layer 190b form respective second interfaces with the NMOS member 140.

In addition, each of the first dielectric layer 180a, the second dielectric layer 180b, the third dielectric layer 190a, and the fourth dielectric layer 190b can be formed from or can include an oxide; a nitride; a carbide; a silicate; a combination thereof (e.g., multiple layers of different materials), or the like. In some examples, the oxide can be embodied in or can include beryllium oxide, magnesium oxide, aluminum oxide, hafnium oxide, zirconium oxide, lanthanum oxide, yttrium oxide, scandium oxide, gadolinium oxide, and the like. In other examples, the nitride can be embodied in or can include boron nitride, aluminum nitride, silicon nitride, and the like.

In yet other example, the carbide can be embodied in or can include wide-bandgap polytypes of silicon carbide, such as 2H and 4H, and the like. In still other examples, the silicates (e.g., hafnium silicate, zirconium silicate, and the like).

In some embodiments, the first dielectric layer 180a can contain a first amount of localized charges having a first defined polarity (e.g., positive or negative), and the second dielectric layer 150b can include a second amount of localized charges having the first defined polarity. The third dielectric layer 190a can contain a third amount of localized charges having a second defined polarity opposite to the first polarity. The fourth dielectric layer 190b can include a fourth amount of localized charges having the second defined polarity. Therefore, the first dielectric layer 180a and the second dielectric layer 180b can be referred to as being “dual” or “complementary” to the third dielectric layer 190a and the fourth dielectric layer 190b.

Each (or, in some embodiments, at least some) of the localized charges in each of the first dielectric layer 180a, the second dielectric layer 180b, the third dielectric layer 190a, and the fourth dielectric layer 190b can be located in the vicinity of point defects present in each of such layers. Point defects can include, for example, vacancies, interstitial atoms (self-interstitial atoms and/or impurity interstitial atoms), dangling bonds, or the like. In some aspects, each of the first dielectric layer 180a, the second dielectric layer 180b, the third dielectric layer 190a, and the fourth dielectric layer 190b can be formed to have a density of point defects in a range from about 10¹² cm⁻² to about 10¹³ cm⁻². Thus, in some embodiments, each one of the first amount of localized charges, the second amount of localized charges, the third amount of localized charges, and the fourth amount of localized charges can range from about 10¹² cm⁻² to about 10¹³ cm⁻². In other embodiments, the density of point defects can be greater than about 10¹³ cm⁻² and, therefore, each one of the first amount of localized charges, the second amount of localized charges, the third amount of localized charges, and the fourth amount of localized charges can be greater than about 10¹³ cm⁻².

The first defined polarity can be opposite a polarity of first mobile carriers (or charges) in the PMOS member 120. The second defined polarity can be opposite a polarity of second mobile carriers (or charges) in the NMOS member 140. Therefore, in response to biasing the solid-state assembly 100, at least some of the first amount of localized charges in the first dielectric layer 180a and the second amount of localized charges in the second dielectric layer 180b can attract mobile carriers (e.g., electrons) in a transport channel within the PMOS member 120. Thus, mobility within the channel can be increased. In addition, at least some of the third amount of localized charges in the third dielectric layer 190a and the fourth dielectric layer 190b can attract mobile carriers (e.g., holes) from another transport channel in the NMOS member 140. Thus, mobility within the other channel also can be increased. As such, performance of a CMOS transistor including the solid-assembly 100 can have improved performance over another CMOS transistor lacking one or more of the first dielectric layer 180a, the second dielectric layer 180b, the third dielectric layer 190a, and the fourth dielectric layer 190b.

As mentioned, the presence of point defects in a dielectric layer (such as the first dielectric layer 180a, the second dielectric layer 180b, the third dielectric layer 190a, and the fourth dielectric layer 190b) in accordance with aspects of this disclosure can permit or otherwise facilitate, at least in part, having localized charges within such dielectric layers. The point defects in the dielectric layer can include neutral defects and/or charged defects, e.g., singly-charged defect(s) and/or multiply-charged defect(s) (doubly-charged defect(s), triply-charged defect(s), and the like). Regardless of a particular charge configuration of a point defect within the dielectric layer, an electronic state energy of the point defect can determine the polarity of the dielectric layer, e.g., a positively charged spacer layer or a negatively charged spacer layer. More specifically and without intending to be bound by theory and/or modeling, in some aspects, the electronic state energy of the point defect relative to a conduction band minimum (CBM) and/or a valence band maximum (VBM) of a material that forms a well within a carrier-doped member (e.g., PMOS member 120 or NMOS member 140) can determine the polarity of the localized charges in the dielectric layer. Specifically, in a scenario in which the electronic state energy of the point defect is greater than the CBM, the polarity of the dielectric layer can be positive. In another scenario in which the electronic state energy is less than the VBM, the polarity of the dielectric layer can be negative. Accordingly, in some aspects, various combinations of the material that forms a well and a low-K dielectric that forms the dielectric layer can provide increased CMOS transistor performance, without reliance on doping of an extension tip (or, in some embodiments, an underlap layer).

In some embodiments, a type of low-K dielectric material (e.g., an oxide, a nitride, a carbide, a silicate) that constitutes a dielectric layer having localized charges, and parameters of a deposition process to form the dielectric layer can be selected or otherwise configured in order to form the dielectric layer having a defined amount of localized charges in accordance with aspects of this disclosure. Such parameters can include, for example, temperature, partial pressures of respective precursor gases, pressure of an environment within a deposition chamber, a combination of the foregoing, or the like. In some embodiments, the parameters can be selected to form a non-stoichiometric compound embodying the low-K material in order to achieve a defined amount of point defects (e.g., vacancies) within the spacer layer. The type of the low-K material and the type(s) of the point defects can determine the electronic structure of the dielectric layer, including electronic states associated with the type(s) of point defects.

More specifically, without intending to be bound by theory and/or modeling, impurity dangling bonds (or, in some embodiments, other types of point defects) can be leveraged to introduce electronic states in the bandgap of a dielectric film or another type of layer that forms a dielectric layer (such as the first dielectric layer 180a, the second dielectric layer 180b, the third dielectric layer 190a, and the fourth dielectric layer 190b). Insofar as the electronic states of the dangling bonds (or, in some embodiments, the other types of point defects) are satisfactorily separated from the energy bandgap of a material (In₁₋ₓGaₓAs, Al₁₋ₓGaₓSb, etc., where x represent a real number indicative of the stoichiometry of the compound) that forms or otherwise constitutes a well of the PMOS member 120 or another well of the NMOS member 140, the electronic states can become either positively charged or negatively charged as a localized charge. In some aspects, such a localized charge in the film or layer can attract mobile carriers of an opposite polarity in the PMOS member 120 or the NMOS member 140, or can repel mobile carries of the same polarity from a transport channel in the PMOS member 120 or the NMOS well 140.

In embodiments in which each of the PMOS member 120 and the NMOS member 140 is formed from an In-rich InGaAs compound, a dielectric layer formed from, for example, one of non-stoichiometric La₂O₃, non-stoichiometric scandium oxide, non-stroichiometric lanthanum silicate, non-stoichiometric scandium silicate can contain localized negative charges; and another dielectric layer formed from, for example, non-stoichiometric Al₂O₃, non-stoichiometric aluminum silicate, non-stoichiometric AlN, non-stoichiometric AlON, non-stoichiometric TiO₂, non-stoichiometric TiON can contain localized positive charges. Specifically, in some embodiments, in order to introduce localized positive charge for a CMOS transistor, an Al-rich and O-deficient solid film can be utilized as the dielectric layer 190a or the dielectric layer 190b.

The solid-state assembly 100 also can include multiple oxide layers, including an oxide layer 195a, an oxide layer 195b, and an oxide layer 195c. Each of the oxide layers can serve as an interlayer dielectric (ILD, and can permit or otherwise facilitate integration of the solid-state assembly 100 into circuitry.

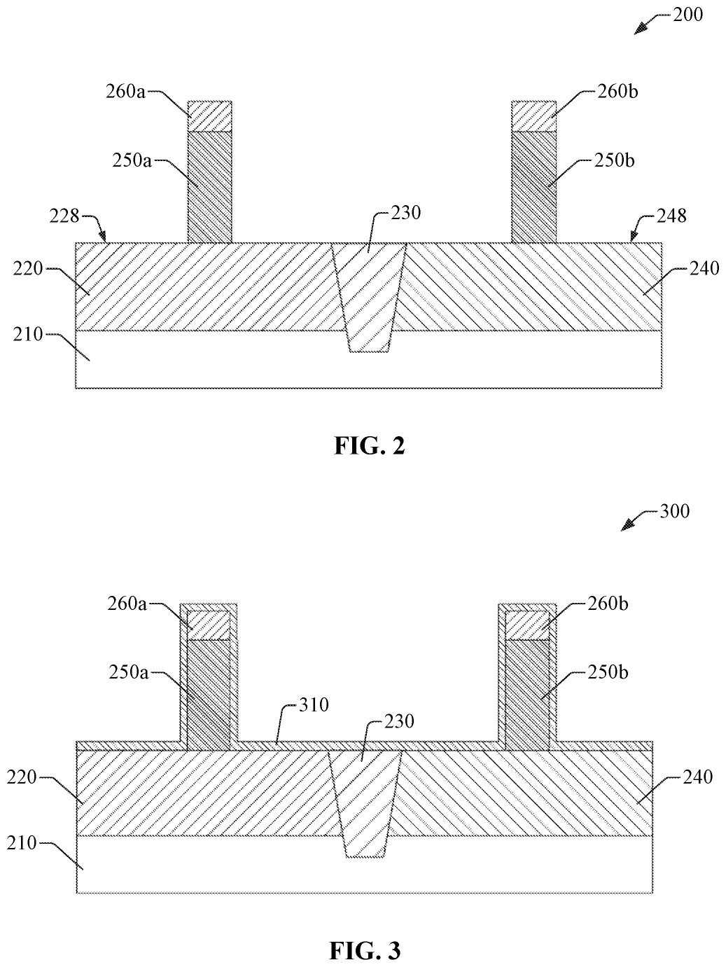

Numerous processes can be implemented to form a CMOS transistor or another type of semiconductor device that includes a solid-state assembly in accordance with aspects of this disclosure. Each of such processes can include multiple stages. After an initial stage to treat a precursor structure, such as a CMOS structure or film, subsequent stages can include treating respective solid structures resulting from previous stages of the process. FIG. 2 illustrates a schematic cross-sectional view of an example solid-state assembly 200 representative of a stage of an example process for fabricating a CMOS transistor or another type of semiconductor device, in accordance with one or more embodiments of the disclosure. The solid-state assembly 200 includes a semiconductor substrate 210, such as a Si substrate, a GaAs substrate, or another type of substrate having a high energy bandgap material. The solid-state assembly 200 also includes a PMOS member 220 and an NMOS member 240 separated from each other by an isolation member 230 (such as a shallow trench isolation (STI) layer). As illustrated, the isolation member 230 can be partially embedded in the semiconductor substrate 210, and forms a first interface with the PMOS member 220 and a second interface with the NMOS member 240. Similar to the PMOS member 120, the PMOS member 220 be embodied in or can include a slab of a first semiconductor material doped n-type, and also can include two non-contiguous regions of semiconductor material doped p+-type. In some embodiments, the first semiconductor material can be embodied in Ge or a III-V semiconductor compound having an energy bandgap less than the energy bandgap of the material that forms the semiconductor substrate 210. Similar to the NMOS member 140, the NMOS member 240 be embodied in or can include a slab of a second semiconductor material doped p-type, and also can include two non-contiguous regions of semiconductor material doped n+-type. In some embodiments, the second semiconductor material can be embodied in Ge or a III-V semiconductor compound having an energy bandgap less than the energy bandgap of the material that forms the semiconductor substrate 210. In some embodiments, the second semiconductor material can be essentially the same as the first semiconductor material—e.g., both such materials can be embodied in Ge, InSb, or nominally the same InGaAs compound. In other embodiments, the second semiconductor material and the first semiconductor material can be different.

The PMOS member 230 can form a first interface 224 with the semiconductor substrate 210 and can include a surface 228 opposite the first interface 224. The NMOS member 240 can form a second interface 244 with the semiconductor substrate 210 and can include a surface 248 opposite the first interface 244. As illustrated in FIG. 2, the solid-state assembly 200 can include a sacrificial gate member 250a formed on a portion of the surface 228, and a sacrificial gate member 250b formed on a portion of the surface 248. As such, the first sacrificial gate member 250a and the second sacrificial gate member 250b can include respective materials that can be formed on a doped semiconductor surface and can be removed (at a later processing stage, for example) with a suitable treatment, such as a wet etching process or a dry etching process. The sacrificial gate member 250a can form an interface with the PMOS member 220, and the sacrificial gate member 250b can form an interface with the NMOS member 240. In some aspects, wet etching relies on a liquid solution for the removal of a material and generally is isotropic. Wet etching can utilize or otherwise rely upon aqueous hydroxide chemistries, including ammonium hydroxide and potassium hydroxide, solution of carboxylic acid/nitric acid/hydrofluoric acid, and solutions of citric acid/nitric acid/hydrofluoric acid. In other aspects, dry etching generally refers to etching that does not rely on a solution for the removal of a material, and generally is anisotropic. Dry etching can rely on plasma (e.g., a gas of electrons) or ions. As such, dry etching includes plasma etching and reactive-ion etching (ME) and its variants, such as deep REI.

A first hard mask (HM) member 260a can cap or otherwise cover the first sacrificial gate member 250b, and a second HM member 260b can cap or otherwise cover the second sacrificial member 250b. Each of the HM members 260a and 260b can permit preserving the sacrificial gate members 250a and 250b during other stages of the process in order to retain real-state for functional gate electrode members in accordance with aspects of this disclosure. Similar to other HM members described herein, each of the HM member 250a and HM member 250b can be formed from or can include silicon nitride, silicon dioxide, silicon oxynitride, silicon carbonitride, silicon carbide, silicon oxycarbonitride, spin-on silicate glass films, a polymeric dielectric film, a non-stoichiometric variation of the foregoing films, a combinations of the foregoing, or the like.

In another stage of the example process for fabricating a CMOS transistor or another type of semiconductor device in accordance with aspects of this disclosure, the solid-assembly 200 can be treated to form the solid-state assembly 300 illustrated in FIG. 3. Specifically, treating the solid-state assembly 200 can include depositing a first dielectric layer 310 on an exposed surface of the solid state-assembly 200. The first dielectric layer 310 can be conformal with the exposed surface and can contain localized charges of a first defined polarity (e.g., positive localized charges or negative localized charges). As such, in some embodiments, depositing the first dielectric layer 310 can include depositing an amount of a first low-K dielectric material by means of one or a combination of numerous deposition processes under deposition conditions that promote incorporation of localized charges of the first defined polarity. Such deposition processes can include, for example, chemical vapor deposition (CVD); atomic layer deposition (ALD); physical vapor deposition (PVD); sputtering; chemical solution deposition; or the like. Chemical vapor deposition can include, for example, metal organic chemical vapor deposition (MOCVD), low-pressure chemical vapor deposition (LPCVD), or plasma enhanced chemical vapor deposition (PECVD). More specifically, in some embodiments, a type of the first low-K dielectric material (e.g., an oxide, a nitride, a carbide, a silicate), and parameters of a deposition process to form the first dielectric layer 310 can be selected or otherwise configured in order to such a layer to contain a defined amount of localized charges in accordance with aspects of this disclosure. Such parameters can include, for example, temperature, partial pressures of respective precursor gases, pressure of an environment within a deposition chamber, a combination of the foregoing, or the like. The parameters can be selected to form a non-stoichiometric compound embodying the first low-K dielectric material in order to achieve a defined amount (e.g., a concentration) of point defects (e.g., vacancies) within the first dielectric layer 310. The type of the low-K material and the type(s) of the point defects can determine the electronic structure of the first dielectric layer 310, including electronic states associated with the point defects.

As disclosed herein, in some embodiments, the semiconductor material that constitutes the PMOS member 220 can include a p-type III-V semiconductor compound (e.g., p-type In₁₋ₓAsₓGa). In addition, non-stoichiometric La₂O₃ can embody or can constitute the first low-K dielectric material that forms the first dielectric layer 310. Thus, in such embodiments, the first low-K dielectric layer 310 can contain a defined amount of positive localized charges.

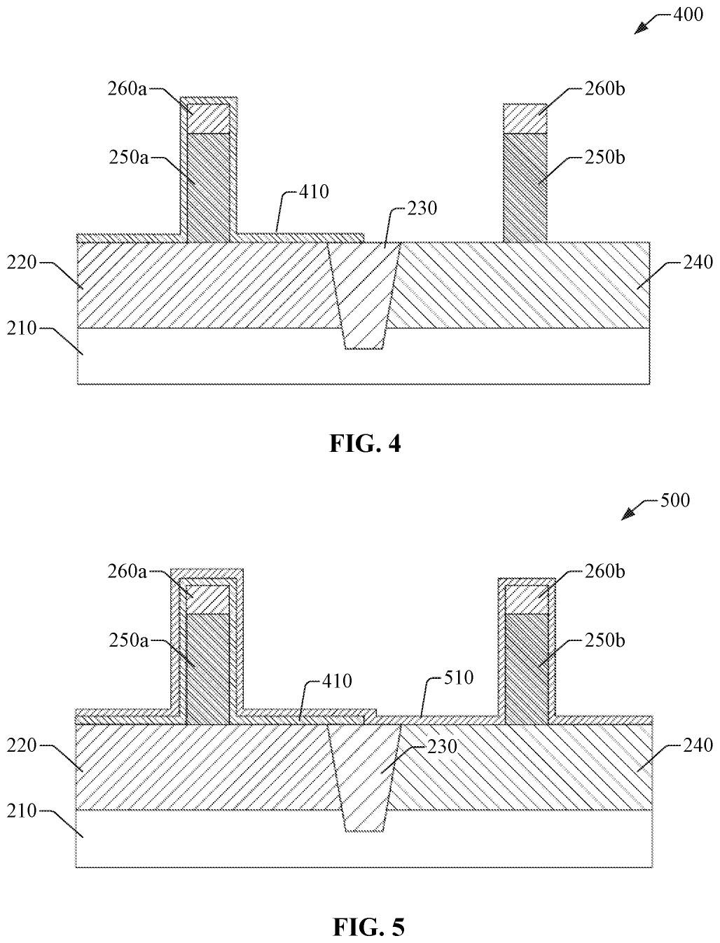

Therefore, a next stage of the example process can include treating the solid-state assembly 300 to remove a portion of the first low-K dielectric layer 310, thus forming the solid-state assembly 400 illustrated in FIG. 4. Selectively removing the portion of the first low-K dielectric layer 310 can result in a second low-K dielectric layer 410 that can cover at least the PMOS member 220. The second low-K dielectric layer 410 also containing localized charges of a same polarity as those in the first low-K dielectric layer 310. In some embodiments, selectively removing the portion of the first low-K dielectric layer 310 can include (i) masking a region of the first low-K dielectric 310 that covers the PMOS member 220 and a portion of the isolation member 230, and (ii) selectively etching an unmasked region of the first low-K dielectric layer 310 covering the NMOS member 240 and another portion of the isolation member 230. Selectively etching such unmasked region can include subjecting the unmasked region to a wet etch process or a dry etch process.

The example process can continue with the formation of a solid thin film having localized charges of a defined polarity opposite to the polarity of the localized charges in the second low-K dielectric layer 410. Specifically, a next stage of the example process can include treating the solid-state assembly 400 to form the solid-state assembly 500 illustrated in FIG. 5. Treating the solid-state assembly 400 can include depositing an amount of a low-K material to form a third low-K dielectric layer 510 that can cover the solid-state assembly 400. In some aspects, the third low-K dielectric layer 510 can be conformal with the second low-K dielectric layer 410 and a remaining portion of the solid-state assembly 400. Such remaining portion including a portion of an exposed surface of the isolation member 230, exposed surfaces of the NMOS member 240, and sidewall surfaces of the sacrificial gate member 250b and the HM member 260b.

As disclosed herein, in some embodiments, the semiconductor material that constitutes the NMOS member 240 can include an n-type III-V semiconductor compound (e.g., n-type In₁₋ₓAsₓGa). In addition, non-stoichiometric Al₂O₃ can embody or can constitute the third low-K dielectric material that forms the third dielectric layer 510. Thus, in such embodiments, the third low-K dielectric layer 510 can contain a defined amount of negative localized charges.

Positive localized charges can be formed in a dielectric material having sufficiently large conduction band offset with respect to a semiconductor material that forms or otherwise constitutes the PMOS member 120 or the NMOS member 140—e.g., there is a sufficient number of unoccupied electron states of donor type in the dielectric layer 180a or the dielectric layer 180b, for example, that have respective electronic energies greater than the bottom conduction band of the semiconductor material. In some embodiments, any dielectric material having a conduction band offset greater than 1 eV can be utilized to form a spacer layer in accordance with aspects of this disclosure. In some embodiments, the low-K dielectric material that forms or otherwise constitute the spacer layer can have a conduction band offset greater than 2 eV, e.g. greater than 3 eV or greater than 4 eV. Sufficient conduction band offset between the low-K dielectric material and the material of the PMOS member 120 or the NMOS member 140 can permit or otherwise facilitate, in response to the growth processing of the selected dielectric material as described below, forming positive localized charge in the spacer layer 170a or the spacer layer 170b.

In some aspects, CVD or ALD can include a chemical process in which one or more reactive precursor gases are introduced into a reaction chamber and directed towards a substrate in order to induce controlled chemical reactions that result in the growth of a desired material on the substrate. The one or more reactive precursor gases may be provided to the reaction chamber at a flow rate from about 5 standard cubic centimeter per minute (sccm) to about 500 sccm, for example, including all values and ranges therein. Each (or, in some embodiments, at least one) of the reactive precursor gas(es) can be provided by means of a carrier gas, such as an inert gas (e.g., argon, helium, or the like). In some embodiments, the reaction chamber can be maintained, during deposition, at a defined pressure and a defined temperature. The pressure can have a magnitude in a range from about 1 milliTorr to about 100 milliTorr, including all values and ranges therein, and the temperature can have a magnitude in a range from about 100° C. to 500° C., including all values and ranges therein. The substrate also can be heated. In some embodiments, the process may be plasma assisted where electrodes are provided within the reaction chamber and are used to ionize the gases. In addition or in other embodiments, plasma may be formed outside of the chamber and then supplied into the reaction chamber. In the reaction chamber, in some aspect, a layer of solid thin film material can be deposited on the surface of the substrate due to reaction of the gas(es).

A substrate placed in the CVD, ALD, or PVD reaction chamber can include, for example, a solid assembly having a semiconductor slab that embodies the PMOS member 120 or the NMOS member 140. The layer of solid thin film material deposited on a surface of such a substrate due to reaction of precursor gases in the reaction chamber can embody or can constitute a spacer layer having positive localized charge in accordance with aspects described herein. A selection of particular one or more precursor gases can depend on the low-K dielectric material that forms or otherwise constitutes the spacer layer. Deposition conditions that permit or otherwise faciliate incorporation of positive localized charges, e.g., formation of native point defects, can include a cation-rich environment in the reaction chamber, the doping of the dielectric material being formed with positively-charged impurity atoms, and/or the addition of negatively-charged hydrogen atoms to the reaction chamber (e.g., a hydrogen ambient growth).

In some embodiments, providing cation-rich growth conditions can include configuring and/or maintaining a partial pressure of cation-precursor species in the reaction chamber nearly at or above a defined threshold, which threshold can be provided either as an absolute value or a value relative to partial pressure of other gasses in the chamber, e.g., such as anion-precursor gases. In some embodiments, establishing cation-rich growth conditions may include ensuring that the respective partial pressure(s) of one or more cation precursor gases can be greater than the partial pressure of the anion precursor gases. For example, the partial pressure of the cation precursor gas(es) can have a magnitude in a range from about one time to about hundred times greater than the partial pressure of the anion precursor gases, including all values and ranges therein. For deposition of a positively charged spacer layer in accordance with aspects of this disclosure, the cation precursor gases can include one or more metal-containing precursors bound by a non-metallic element, such as chlorine, fluorine, bromine, iodine, or the like. For instance, in some embodiments, the cation precursor gases can include beryllium chloride; magnesium chloride; aluminum chloride; hafnium chloride; zirconium chloride; lanthanum chloride; yttrium chloride; scandium chloride; gadolinium chloride; analogous metal-based precursors bound by fluorine, bromine, iodine, etc.; a combination thereof; or the like In other embodiments, the cation precursor gases can include metal-based carbon-containing and/or metal-based hydrogen-containing precursor gases, such as metal-containing amidinates and actinates.

Doping with impurity atoms that lead to positive localized charges within a spacer layer of this disclosure can be performed by in-situ doping during the CVD or ALD deposition of an amount of low-K material that forms or otherwise constitutes the spacer layer. In some embodiments, impurity atoms that lead to positive localized charges can be incorporated into a low-K dielectric material being grown by means of introduction of impurity-level quantities of dopant-containing precursor gases during the growth, and controlled through the partial pressure of such gases. In embodiments in which the low-K dielectric material is embodied in an oxide or a silicate, suitable dopant atoms to be provided in a dopant-containing precursor gas can include fluorine, chlorine, bromine, halogens, or the like. In embodiments in which the low-K dielectric material is embodied in a nitride, suitable dopant atoms to be provided in a dopant-containing precursor gas can include oxygen, sulfur, selenium, or other elements from the oxygen group of the periodic table. In embodiments in which the low-K dielectric material is embodied in a carbide, suitable dopant atoms to be provided in a dopant-containing precursor gas can include nitrogen, phosphorus, arsenic, or other elements from the nitrogen group of the periodic table.

In some embodiments, providing a hydrogen ambient growth can include incorporating, during growth, atomic hydrogen into the low-K dielectric material that forms a dielectric layer (e.g., dielectric layer 180a or dielectric layer 180b) in accordance with aspects of this disclosure. To that end, in one example, a negatively-charged hydrogen ambient (such as hydrogen gas, PE-atomic hydrogen, water, and the like) can be provided during deposition of the spacer layer. The amphoteric nature of atomic hydrogen can permit or otherwise facilitate neutralizing the charge of intentionally incorporated positively-charged point defects (e.g., vacancies, impurities, or the like).

An as-deposited dielectric layer can be annealed in order to remove at least a portion of incorporated negative hydrogen atoms from the spacer layer, thus retaining positive localized charges. In some embodiments, annealing the spacer layer can include heating up a solid-state assembly including the spacer layer to a temperature of about 200 degrees Celsius (° C.) to about 600° C. for a defined period of about 1 minute to about 120 minutes. In some embodiments, low-K dielectric materials having oxygen coordination equal to or greater than four in a stoichiometric compound can be more suitable for the application of the disclosed hydrogen strategy for incorporation of positive localized charge. Such low-K materials can include beryllium oxide, magnesium oxide, boron nitride, aluminum nitride, silicon carbide, and the like.

As disclosed herein, negative localized charges can be formed in a low-K dielectric material that has sufficiently large valence band offset with respect to a semiconductor material that forms or otherwise constitutes the PMOS member 120 or the NMOS member 140—e.g., there is a sufficient number of occupied electron states of acceptor type in the dielectric layer 190a or the dielectric layer 190b that have respective electronic energies less than the valence band maximum of the semiconductor material. A dielectric material having a sufficiently large valence band offset from that of the semiconductor material can be utilized to form a spacer layer in accordane with aspects of this disclosure. In some embodiments, any low-K dielectric material that has a valence band offset greater than zero can be selected to form a negatively-charged spacer layer. For instance, the low-K dielectric material can be selected to have a valence band offset greater than 1 eV, e.g. greater than 2 eV or greater than 3 eV. Sufficient valence band offset between the low-K dielectric material and the material of the PMOS member 120 or the NMOS member 140 can permit or otherwise facilitate, in response to the growth processing of the selected dielectric material as described below, forming negative localized charge in the dielectric layer 190a and the dielectric layer 190b.

A dielectric layer that includes negative localized charges can be formed by depositing an amount of a low-K dielectric material according to one or a combination of numerous deposition processes under deposition conditions that promote incorporation of negative localized charge within the spacer layer. As mentioned, in some aspects, deposition parameters can determine such deposition conditions. The deposition processes can include, for example, CVD; ALD; PVD; sputtering; chemical solution deposition; or the like. Chemical vapor deposition can include, for example, MOCVD, LPCVD, or PECVD.

A selection of particular one or more anion precursor gases can depend on the low-K dielectric material that forms or otherwise constitutes the spacer layer including negative localized charges. Deposition conditions that promote the formation of negative localized charges, e.g. the formation of native point defects, can include the formation or retention of an anion-rich environment within the reaction chamber, the doping of the low-K dielectric material with negatively charged impurity atoms during deposition, and/or the addition of positively-charged hydrogen atoms to the reaction chamber (e.g., the provision of a hydrogen ambient growth environment).

In some embodiments, providing anion-rich deposition conditions can include configuring and/or maintaining the partial pressure of anion-precursor species in the reaction chamber nearly at or above a defined threshold. The threshold can be provided either as an absolute value or a value relative to partial pressure of other gasses in the chamber, such as cation-precursor gases. In one example, providing an anion-rich deposition condition can include configuring and maintaining the partial pressure of an anion precursor gas at a level that is greater than the partial pressures of respective cation precursor gases. For example, the partial pressure of the anion precursor gas can have a magnitude in range from about one time to about hundred times greater than the partial pressure of the cation precursor gases, including all values and ranges therein. For deposition of the negative fixed charge dielectric layer as described herein, the anion precursor gases can include, for example, one or more of oxygen-containing precursors (e.g. oxygen gas, water, hydrogen peroxide, etc.); nitrogen-containing precursors (e.g. nitrogen gas, ammonia, nitrous oxide, etc.); or carbon-containing precursors (e.g. carbon dioxide, carbon monoxide, methane, etc.).

Doping with impurity atoms that lead to negative localized charges in a spacer layer of this disclosure can be performed by in-situ doping during the CVD or ALD deposition of an amount of a low-K material that forms or otherwise constitutes the spacer layer. Impurity atoms that can lead to negative localized charges can be incorporated into the low-K dielectric material by means of the introduction of impurity-level amounts of dopant-containing precursor gases during the deposition, and can be controlled through the partial pressure of such gases. In embodiments in which the low-K dielectric material is embodied in or includes an oxide or a silicate, suitable dopant atoms to be provided in a dopant-containing precursor gas can include nitrogen, phosphorus, arsenic, or other elements from the nitrogen group of the periodic table. In an embodiment in which the low-K dielectric material is embodied in or includes a nitride, suitable dopant atoms to be provided in a dopant-containing precursor gas can include carbon, silicon, germanium, or elements from the carbon group of the periodic table. In embodiments in which the low-K dielectric material is embodied in or includes a carbide, suitable dopant atoms to be provided in a dopant-containing precursor gas can include boron, aluminum, gallium, or other elements from the boron group of the periodic table.

Providing hydrogen-ambient growth for a spacer layer in accordance with aspects of this disclosure can include incorporating atomic hydrogen into a low-K dielectric material during the deposition of the spacer layer. To that end, in some embodiments, a positively charged hydrogen ambient can be provided during growth (such as hydrogen gas, PE-atomic hydrogen, water, and the like). The amphoteric nature of atomic hydrogen can permit or otherwise facilitate neutralizing the charge of intentionally incorporated negatively-charged point defects (e.g., vacancies, impurities, or the like).

An as-deposited lining film (e.g., spacer layer 170a or spacer layer 170b) can be annealed in order to remove at least a portion of incorporated positive hydrogen atoms from the spacer layer, thus retaining positive localized charges. In some embodiments, annealing the spacer layer can include heating up a solid-state assembly including the as-deposited lining film to a temperature in a range from about 200° C. to about 600° C. for a defined period in a range from about 1 minute to about 120 minutes.

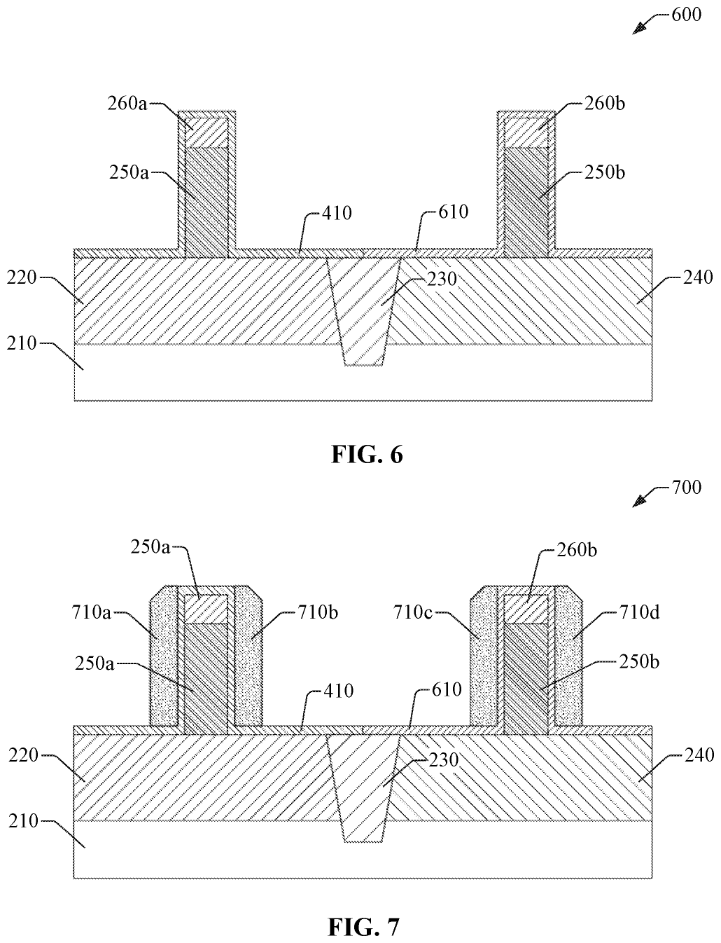

Similar to the removal of a portion of the low-K dielectric layer 310, the example method also can include a stage in which the solid-state assembly 500 can be treated to remove a portion of the low-K dielectric layer 510, thus forming the solid-state assembly 600 illustrated in FIG. 6. In one aspect, the portion of the low-K dielectric layer 510 that is removed includes the portion that is conformal with the second low-K dielectric layer 510. Accordingly, in one aspect, selectively removing the portion of the third low-K dielectric layer 310 can result in a fourth low-K dielectric layer 610 that can cover at least the NMOS member 240. The fourth low-K dielectric layer 410 also containing localized charges of a same polarity as those charges in the third low-K dielectric layer 510. In some embodiments, selectively removing the portion of the third low-K dielectric layer 310 can include (i) masking a region of the third low-K dielectric 510 that covers the NMOS member 240 and a portion of the isolation member 230, and (ii) selectively etching an unmasked region of the third low-K dielectric layer 310 covering the second low-K dielectric layer 510. Selectively etching such unmasked region can include subjecting the unmasked region to a wet etch process or a dry etch process.

As is illustrated in FIG. 6, each of the second low-K dielectric layer 410 and the fourth low-K dielectric layer 610 has sidewalls forming respective interfaces with a sacrificial gate member—e.g., sacrificial gate member 250a and sacrificial gate member 250b. Therefore, a next stage of the example process to form a CMOS transistor or another semiconductor device in accordance with embodiments of this disclosure can include forming multiple spacer layers adjoining or otherwise in contact with respective sidewalls. To that end, in some embodiments, the solid-state assembly 600 can be treated to form the solid-state assembly 700 illustrated in FIG. 7. Treating the solid-state assembly 600 can include, for example, patterning a first spacer layer 710a, a second spacer layer 710b, a third spacer layer 720a, and a fourth spacer layer 720b on the solid-state assembly 600. As illustrated in FIG. 7, the first spacer layer 710a and the second spacer layer 710b can be patterned proximate to the PMOS member 220, and each of such layers can have an essentially uniform thickness t (a real number in units of length) in a range from about 2 nm to about 15 nm. As mentioned, t can embody a length of an extension tip for a source contact and a drain contact in the PMOS region of the CMOS transistor being fabricated. In addition, the third spacer layer 720a and the fourth spacer layer 720b can be patterned proximate to the NMOS member 240, and each of such layers also can have the essentially uniform thickness t. For those layers, as mentioned, t can embody a length of an extension tip for a source contact and a drain contact in the NMOS region of the CMOS transistor.

In some embodiments, the spacer layers 710a, 710b, 720a, and 720b can be patterned concurrently (or, in some embodiments, nearly concurrently). Yet, in embodiments in which the low-K dielectric material that constitutes the spacer layers 710a and 710b is different from the low-K dielectric material that constitutes the spacer layers 720a and 720b, the spacer layers 710a and 710b can be patterned in a different patterning process from that of the spacer layers 720a and 720b. Thus, similar to the spacer layers 150a-150d in the solid-assembly 100 in FIG. 1, each of the first spacer layer 710a, a second spacer layer 710b, a third spacer layer 720a, and a fourth spacer layer 720b can be formed from or can include, in some embodiments, respective low-K dielectric materials. For instance, the first spacer layer 710 and the second spacer layer 710a can include a same low-K dielectric material that can form satisfactory interfaces (e.g., interfaces with a specific density of defects, point defects or otherwise) with the other low-K material (e.g., non-stoichiometric La₂O₃) that forms the low-K dielectric layer 410. In addition, the third spacer layer 720a and the fourth spacer layer 720b can include another low-K dielectric material that can form satisfactory interfaces with yet another low-K material (e.g., non-stoichiometric Al₂O₃) that forms the low-K dielectric layer 610.

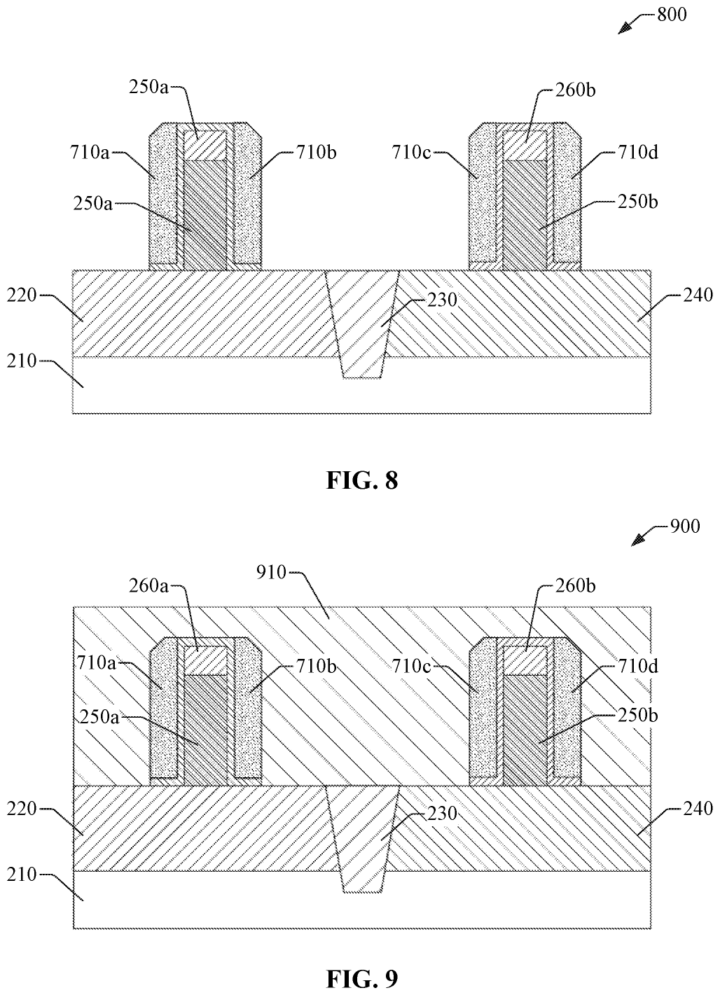

In yet another stage of the example process, exposed portions of the low-K dielectric layer 410 and other exposed portions of low-K dielectric layer 610 can be removed in order to permit or otherwise facilitate formation of transport contacts (e.g., source contact and drain contact) in the PMOS member 220 and the NMOS member 240. As such, as part of the example process, the solid-state assembly 700 can be treated form the solid-state assembly 800 illustrated in FIG. 8. Treating the solid-state assembly 700 can include selectively removing portions of the low-K dielectric layer 410 that are respectively adjacent, yet not in contact with, the first spacer layer 710a and the second spacer layer 710b. As such, in some embodiments, in order to remove such portions of the of the low-K dielectric layer 410, treating the solid-state assembly 700 can include selectively etching the first low-K dielectric material that constitutes such portions of the low-K dielectric layer 410. The selective etching can include, for example, subjecting the low-K dielectric layer 410 to a wet etch process or a dry etch process. The selective removal of the portions of the low-K dielectric layer 410 and the other portions of the low-K dielectric layer 610 can result in the formation of a first dielectric lining 810 and a second dielectric lining 820. In some aspects, the first dielectric lining 810 and the second dielectric lining 820 can contain respective amounts of localized charges of respective defined polarities.

Treating the solid assembly 700 can further include selectively removing other portions of the low-K dielectric layer 610 that are respectively adjacent, yet not in contact with, the third spacer layer 720a and the fourth spacer layer 720b. Thus, in some embodiments, in order to remove such portions of the low-K dielectric layer 610, treating the solid-state assembly 700 can include selectively etching the second low-K dielectric material that constitutes such portions of the low-K dielectric layer 610. The selective etching can include, for example, subjecting the low-K dielectric layer 610 to a wet etch process or a dry etch process.

Transport contacts, e.g., source contact and drain contacts, can be formed in the PMOS member 220 and the NMOS member 240. The transports contacts (not depicted in FIG. 8) can be formed by means of numerous processes, including ion implantation, carrier-doped epitaxial layer (epilayer) deposition, a combination thereof, or the like. After formation of transport contacts, a next stage in the example process for fabricating a CMOS transistor in accordance with embodiments of this disclosure can include capping or otherwise covering the solid-state structure 800 with an interlayer dielectric (ILD) material (such as a low-K dielectric material) resulting in the solid-state structure 900 illustrated in FIG. 9. As illustrated, the capping can include depositing an amount of the ILD material to coat the solid-state structure 800 with an ILD film 910 having an overburden region with respect to the first charged lining 810 and the second charged lining 820. The amount of the dielectric material can be deposited by one or a combination of deposition processes, such as CVD, ALD, PVD, sputtering, chemical solution deposition, or the like. The overburden region can simplify, for example, the polishing of the solid-state structure 900 in other stages of the example process.

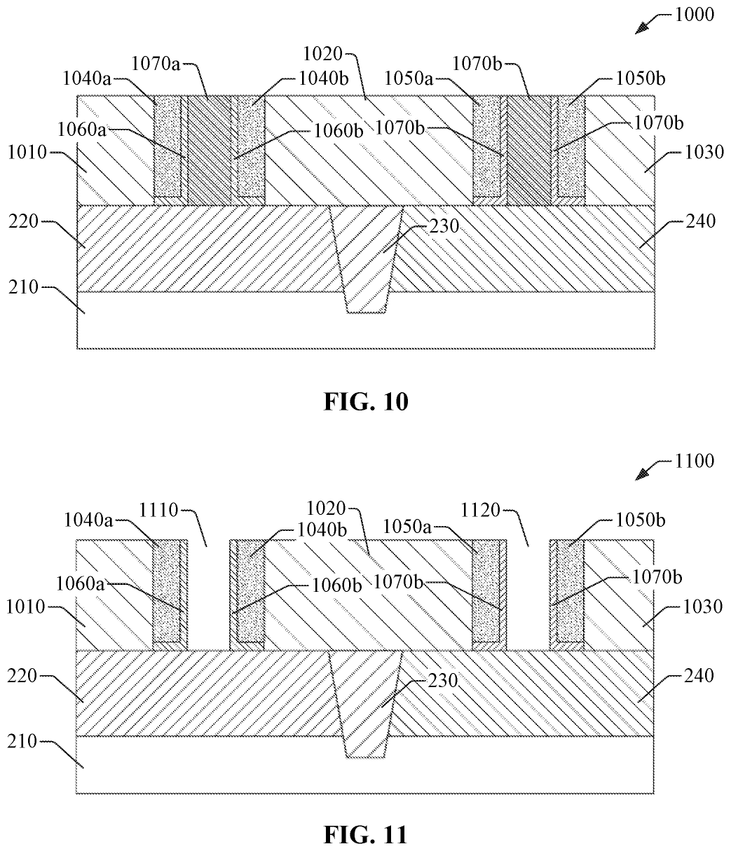

In another stage of the example process for fabricating a CMOS transistor or another type of semiconductor device in accordance with aspects of this disclosure, the solid-state assembly 900 can be planarized in order to expose an essentially flat surface of the sacrificial gate member 250a and another essentially flat surface of the sacrificial gate member 250b, thus resulting in the solid-state assembly 1000 illustrated in FIG. 10. Planarizing the solid-state assembly 900 can include, for example, polishing the solid-state assembly 900 to remove the overburden region of the ILD film 910; respective portions of the first dielectric lining 810 and the second dielectric lining 820; the HM member 260a and the HM member 260b; and respective portions of the first spacer layer 710a, a second spacer layer 710b, a third spacer layer 720a, and a fourth spacer layer 720b. As mentioned, the solid-state assembly 900 can be polished chemically and/or mechanically (as in a chemical mechanical polish (CMP) process, for example). Therefore, in some aspects, the solid-state assembly 1000 can include a first ILD member 1010, a second ILD member 1020, and a third ILD member 1030, each having an essentially flat surface. In addition or in other aspects, the solid-state assembly 1000 can include a first sacrificial gate member 1080a and a second sacrificial gate member 1080b. Further or in yet other aspects, the solid-state assembly 1000 can include multiple composite structures, each including a spacer layer forming an interface with a lining film. Specifically, the multiple composite structures include a first composite structure can include a spacer layer 1040a and a lining film 1060a; a second composite structure can include a spacer layer 1040b and a lining film 1060b; a third composite structure can include a spacer layer 1050a and a lining film 1070a; and a fourth composite structure can include a spacer layer 1050b and a lining film 1070b. In one aspect, the lining film 1060a and the lining film 1060b can form respective interfaces with the sacrificial gate member 1070a. In addition or in another aspect, the lining film 1070a and the lining film 1070b can form respective interfaces with the sacrificial gate member 1070b.

Respective exposed surfaces of the sacrificial gate member 1080a and the sacrificial gate member 1080 can permit or otherwise facilitate removing such members to create respective recesses in order to form functional gate electrode members. Therefore, in another stage of the example method for fabricating a CMOS transistor in accordance with aspects of the disclosure can include treating the solid-state assembly 1000 to form the solid-state assembly 1100 illustrated in FIG. 11. More specifically, in some embodiments, treating the solid-state assembly 1000 can include selectively etching the sacrificial gate member 1080a and the sacrificial gate member 1080b to form, respective, a first recess 1110 and a second recess 1120. Similar to other stages of the example process, the selective etching can include subjecting the sacrificial gate member 1080a and the sacrificial gate member 1080b to one or more of a wet etch process or a dry etch process.

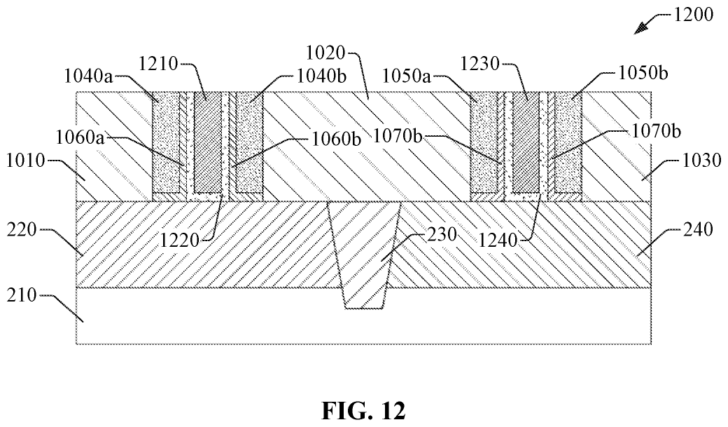

Thus, in some aspects, the sacrificial gate members 1080a and 1080b can permit or otherwise facilitate forming sidewalls included in each of the lining films 1060a and 1060a, each of which films contains localized charges of a defined charge polarity. In other aspects, as mentioned, the sacrificial gate members 1080a and 1080b can preserve respective regions for the formation of a functional gate electrode during the fabrication of a CMOS transistor. To that end, the solid structure 1100 can be treated to form the solid structure 1200 illustrated in FIG. 12. Treating the solid structure 1200 can include forming a first dielectric lining member 1220 and a second dielectric lining member 1240. Each of the first dielectric lining member 1220 and the second dielectric lining member 1240 can serve as a gate dielectric. Depositing the first dielectric lining member 1220 and the second dielectric lining member 1240 can include subjecting, respectively, a first surface of the first recess 1110 and the second recess 1120 to ALD (or, in some embodiments, CVD) of an amount of a high-K dielectric material. As illustrated, the first and the second dielectric lining members 1220 and 1240 can be respectively conformal with first and second exposed surfaces of the first recess 1110 and a second recess 1120. In some embodiments, each of the first dielectric lining member 1220 and the second dielectric member 1240 can have a substantially uniform thickness having a magnitude in a range from about 1 nm to about 5 nm.

Treating the solid structure 1100 also can include depositing a first gate electrode member 1210 and a second gate electrode member 1230. Depositing the first gate electrode member 1210 can include, for example, depositing a first amount of a conductive material on an exposed surface (not depicted) of the first dielectric lining member 1220. The conductive material can include polysilicon, a metal, a conductive ceramic, a conductive polymer, or the like. The metal can include one or more of copper, aluminum, tungsten, titanium, tantalum, silver, gold, palladium, platinum, zinc, nickel, or an alloy of two or more of the foregoing metals. The first amount of the first conductive material can be deposited, in some embodiments, by subjecting such a surface to one or a combination of deposition processes (e.g., CVD, ALD, sputtering or another type of PVD, or the like). Depositing the second gate electrode member 1230 can be achieved in a similar manner by depositing a second amount of the conductive material on an exposed surface (not depicted) of the second dielectric lining member 1240. Depositing the second amount of the conductive material can include subjecting such a surface to one or a combination of deposition processes.

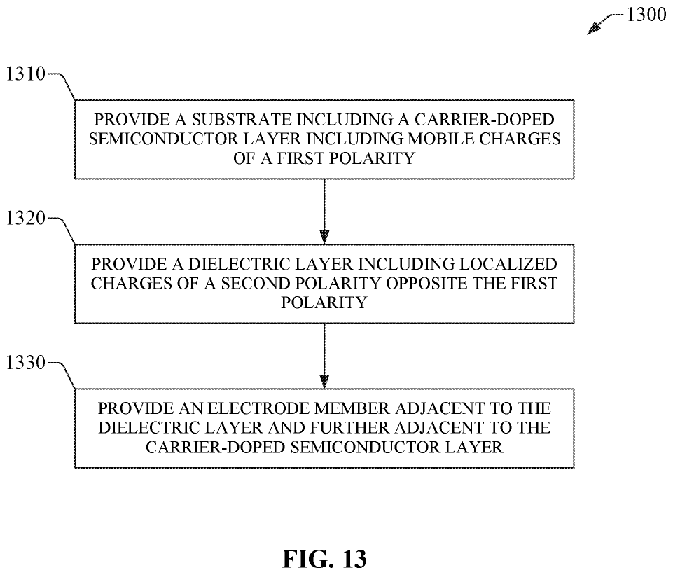

In view of the various aspects of solid-state assemblies and solid-state devices includes therein, a number of processes or methods for fabricating such assemblies can be implemented in accordance with aspects of this disclosure. As an illustration, FIG. 13 presents an example of a method 1300 of fabricating a solid-state device in accordance with one or more embodiments of the disclosure. At block 1310, a substrate including a carrier-doped semiconductor layer including mobile charges of a first polarity can be provided. As described in this disclosure, in some embodiments, such a substrate can be embodied in a CMOS substrate including the semiconductor substrate 110, the PMOS member 120, the isolation member 130, and the NMOS member 140. As such the carrier-doped semiconductor layer can be embodied in or can include the PMOS member 120 or the NMOS member 140. In other embodiments, also as described in this disclosure, the substrate that is provided at block 1310 can be embodied in a CMOS substrate including the semiconductor substrate 210, the PMOS member 220, the isolation member 230, and the NMOS member 240. As such the carrier-doped semiconductor layer can be embodied in or can include the PMOS member 120 or the NMOS member 140.

At block 1320, a dielectric layer including localized charges of a second polarity can be provided. In some aspects, the second polarity can be opposite the first polarity. In some embodiments, providing the dielectric layer can include forming a sacrificial member on a surface of the carrier-doped semiconductor layer. The sacrificial member can extend from the surface to a distal end along a direction substantially perpendicular to the surface. In one example, the sacrificial member can be embodied in or can include the heterostructure formed from the sacrificial gate member 250a and HM member 260a or the other heterostructure formed from the sacrificial gate member 250b and the HM member 260b. In addition or in other embodiments, providing the dielectric layer can include forming a conformal dielectric layer on the sacrificial member and the surface of the carrier-doped semiconductor layer, resulting in a coated sacrificial member. Forming the conformal dielectric layer can include, in some embodiments, depositing an amount of a low-K dielectric material having a first conduction band minimum (CBM) energy greater than a second CBM energy of a semiconductor compound forming the carrier-doped semiconductor layer. In addition or in other embodiments, depositing the amount of a low-K dielectric material can include subjecting the sacrificial member and the surface of the carrier-doped semiconductor layer to chemical vapor deposition (CVD) or atomic layer deposition (ALD) of the amount of the low-K dielectric material. The depositing also can include maintaining, during deposition within a reactor, a first partial pressure of cation-precursor species above a second partial pressure of anion-precursor species. Further or in yet other embodiments, depositing the amount of the low-K dielectric material can include injecting negatively-charged hydrogen atoms into the reactor during deposition, resulting in a second amount of negatively-charged hydrogen atoms being incorporated into the amount of the low-K dielectric material.

As described in this disclosure, in some embodiments, forming the conformal dielectric layer can include depositing an amount of a low-K dielectric material having a first valence band maximum (VBM) energy less than a second VBM energy of a semiconductor compound forming the carrier-doped semiconductor layer. In at least some embodiments, depositing the amount of such a low-K dielectric can include subjecting the sacrificial member and the surface of the carrier-doped semiconductor layer to chemical vapor deposition (CVD) or atomic layer deposition (ALD) of the amount of the low-K dielectric material. In addition or in other embodiments, the depositing further comprises maintaining, during deposition within a reactor, a first partial pressure of anion-precursor species above a second partial pressure of cation-precursor species. Further or in yet other embodiments, depositing the amount of such a low-K dielectric material can include injecting positively-charged hydrogen atoms into the reactor during deposition, resulting in a second amount of positively-charged hydrogen atoms being incorporated into the amount of the low-K dielectric material.

In addition, while not illustrated in FIG. 13, providing the dielectric layer at block 1320 can include forming a first spacer layer and a second spacer layer on a portion of the conformal dielectric layer, the first spacer layer adjoining a first sidewall of the coated sacrificial member and the second spacer layer adjoining a second sidewall of the coated sacrificial member, the second sidewall being opposite to the first sidewall. Further or in other embodiments, providing the dielectric layer can include removing a second portion of the conformal dielectric layer. Further or in yet other embodiments, providing the dielectric layer can include removing an end portion of the coated sacrificial member opposite the surface of the carrier-doped semiconductor layer. Furthermore or in still other embodiments, providing the dielectric layer further can include removing the sacrificial member, resulting in an opening exposing a portion of the surface of the carrier-doped semiconductor layer.

At block 1330, an electrode member adjacent to the dielectric layer and further adjacent to the carrier-doped semiconductor layer can be provided. As described in this disclosure, in some embodiments, providing the electrode member can include forming a high-K dielectric layer arranged as a lining in the opening described above, resulting in a second opening. In addition, providing the electrode can include filling the second opening with a conductive material.

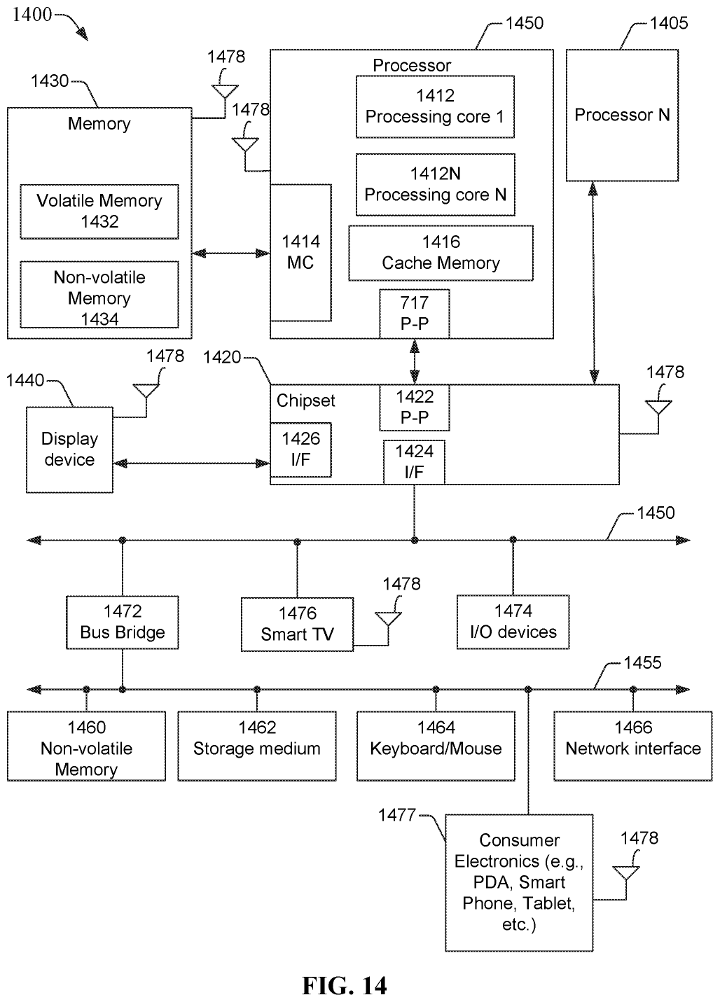

FIG. 14 depicts an example of a system 1400 according to one or more embodiments of the disclosure. In one embodiment, system 1400 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1400 can include a system on a chip (SOC) system or a system-in-package (SiP).

In one embodiment, system 1400 includes multiple processors including processor 1410 and processor N 1405, where processor 1405 has logic similar or identical to the logic of processor 1410. In one embodiment, processor 1410 has one or more processing cores (represented here by processing core 1412 and processing core 1412N, where 1412N represents the Nth processor core inside processor 1410, where N is a positive integer). More processing cores can be present (but not depicted in the diagram of FIG. 14). In some embodiments, processing core 1412 includes, but is not limited to, pre-fetch logic to fetch instructions, decode logic to decode the instructions, execution logic to execute instructions, a combination thereof, or the like. In some embodiments, processor 1410 has a cache memory 1416 to cache instructions and/or data for system 1400. Cache memory 1416 may be organized into a hierarchical structure including one or more levels of cache memory.

In some embodiments, processor 1410 includes a memory controller (MC) 1414, which is configured to perform functions that enable the processor 1410 to access and communicate with memory 1430 that includes a volatile memory 1432 and/or a non-volatile memory 1434. In some embodiments, processor 1410 can be coupled with memory 1430 and chipset 1420. Processor 1410 may also be coupled to a wireless antenna 1478 to communicate with any device configured to transmit and/or receive wireless signals. In one embodiment, the wireless antenna interface 1478 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1432 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1434 includes, but is not limited to, flash memory, phase change memory (PCM), read-only memory (ROM), electrically erasable programmable read-only memory (EEPROM), or any other type of non-volatile memory device.

Memory device 1430 stores information and instructions to be executed by processor 1410. In one embodiment, memory 1430 may also store temporary variables or other intermediate information while processor 1410 is executing instructions. In the illustrated embodiment, chipset 1420 connects with processor 1410 via Point-to-Point (PtP or P-P) interface 1417 and P-P interface 1422. Chipset 1420 enables processor 1410 to connect to other elements in system 900. In some embodiments of the disclosure, P-P interface 1417 and P-P interface 1422 can operate in accordance with a PtP communication protocol, such as the Intel® QuickPath Interconnect (QPI) or the like. In other embodiments, a different interconnect may be used.

In some embodiments, chipset 1420 can be configured to communicate with processor 1410, 1405N, display device 1440, and other devices 1472, 1476, 1474, 1460, 1462, 1464, 1466, 1477, etc. Chipset 1420 may also be coupled to the wireless antenna 1478 to communicate with any device configured to transmit and/or receive wireless signals.

Chipset 1420 connects to display device 1440 via interface 1426. Display 1440 may be, for example, a liquid crystal display (LCD), a plasma display, cathode ray tube (CRT) display, or any other form of visual display device. In some embodiments of the disclosure, processor 1410 and chipset 1420 are integrated into a single SOC. In addition, chipset 1420 connects to bus 1450 and/or bus 1455 that interconnect various elements 1474, 1460, 1462, 1464, and 1466. Bus 1450 and bus 1455 may be interconnected via a bus bridge 1472. In one embodiment, chipset 1420 couples with a non-volatile memory 1460, a mass storage device(s) 1462, a keyboard/mouse 1464, and a network interface 1466 via interface 1424 and/or 1404, smart TV 1476, consumer electronics 1477, etc.

In one embodiment, mass storage device(s) 1462 can include, but not be limited to, a solid state drive, a hard disk drive, a universal serial bus flash memory drive, or any other form of computer data storage medium. In one embodiment, network interface 1466 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 14 are depicted as separate blocks within the system 900, the functions performed by some of these blocks may be integrated within a single semiconductor circuit or may be implemented using two or more separate integrated circuits. For example, although cache memory 1416 is depicted as a separate block within processor 1410, cache memory 1416 or selected elements thereof can be incorporated into processor core 1412.

It is noted that the system 1400 described herein may be any suitable type of microelectronics packaging and configurations thereof, including, for example, system in a package (SiP), system on a package (SOP), package on package (PoP), interposer package, 3D stacked package, etc. Further, any suitable type of microelectronic components may be provided in the semiconductor packages, as described herein. For example, microcontrollers, microprocessors, baseband processors, digital signal processors, memory dies, field gate arrays, logic gate dies, passive component dies, MEMSs, surface mount devices, application specific integrated circuits, baseband processors, amplifiers, filters, combinations thereof, or the like may be packaged in the semiconductor packages, as disclosed herein. The semiconductor devices (for example, the semiconductor device described in connection with FIG. 1) or other types of semiconductor devices, as disclosed herein, may be provided in any variety of electronic device including consumer, industrial, military, communications, infrastructural, and/or other electronic devices.

The semiconductor devices or other types of solid-state devices, as described herein, may be embody or may constitute one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system and the one or more processors and any chipset included in an electronic device may be from a family of Intel® processors and chipsets, such as the Intel® Atom® processor(s) family or Intel-64 processors (e.g., Sandy Bridge®, Ivy Bridge®, Haswell®, Broadwell®, Skylake®, etc.).

Additionally or alternatively, the semiconductor devices, as described herein, may embody or may constitute one or more memory chips or other types of memory devices. The memory chips may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR) SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, the electronic device in which the semiconductor devices in accordance with this disclosure are provided may be a computing device. Such a computing device may house one or more boards on which the semiconductor package connections may be disposed. The board may include a number of components including, but not limited to, a processor and/or at least one communication chip. The processor may be physically and electrically connected to the board through, for example, electrical connections of the semiconductor package. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

The semiconductor devices and other types of solid assemblies in accordance with aspects of the disclosure may be used in connection with one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system and the one or more processors and any chipset included in an electronic device may be from a family of Intel® processors and chipsets, such as the Intel® Atom® processor(s) family or Intel-64 processors (for example, Sandy Bridge®, Ivy Bridge®, Haswell®, Broadwell®, Skylake®, etc.).

Additionally or alternatively, semiconductor devices and other types of solid assemblies in accordance with aspects of the disclosure may be used in connection with one or more memory chips. The memory may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR) SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, an electronic device in which the semiconductor devices and other types of solid assemblies in accordance with aspects of the disclosure can be used and/or provided may be a computing device. Such a computing device may house one or more boards on which the interconnects may be disposed. The board may include a number of components including, but not limited to, a processor and/or at least one communication chip. The processor may be physically and electrically connected to the board through, for example, electrical connections of the interconnects. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

### Further Examples

The following example embodiments pertain to further embodiments of this disclosure. Example 1 is a solid assembly, comprising: a carrier-doped semiconductor layer including mobile charges of a first polarity; a dielectric layer including localized charges of a second polarity opposite the first polarity; an electrode member adjacent to the dielectric layer and further adjacent to the carrier-doped semiconductor layer.

In Example 2, the solid assembly of Example 1 can optionally include a second carrier-doped semiconductor layer including mobile charges of the second polarity; a second dielectric layer including second localized charges of the first polarity; a second electrode member adjacent to the second dielectric layer and further adjacent to the second carrier-doped semiconductor layer.

In Example 3, the solid assembly of any one of Examples 1-2 can optionally include a carrier-doped semiconductor layer comprising a III-V semiconductor compound doped n-type, and wherein the second polarity is positive polarity.

In Example 4, the solid assembly of any one of examples 1-3 can optionally include a carrier-doped semiconductor layer comprising a III-V semiconductor compound doped n-type, and wherein the second polarity is negative polarity.

In Example 5, the solid assembly of any one of Examples 1-4 can optionally include the dielectric layer comprising a low-K material selected from the group comprising an oxide, a nitride, a carbide, and a silicate.

In Example 6, the solid assembly of Example 5 can optionally include oxide comprising beryllium oxide, magnesium oxide, aluminum oxide, hafnium oxide, zirconium oxide, lanthanum oxide, yttrium oxide, scandium oxide, or gadolinium oxide.

In Example 7, the solid assembly of any one of Examples 5-6 can optionally include nitride comprising boron nitride, aluminum nitride, or silicon nitride.

In Example 8, the solid assembly of any one of Examples 5-7 can optionally include carbine comprising a wide-bandgap polytype of silicon carbide.

In Example 9, the solid assembly of any one of Examples 5-8 can optionally include silicate comprising hafnium silicate or zirconium silicate.

In Example 10, the solid assembly of any one of Examples 5-9 can optionally include the dielectric layer having a substantially uniform thickness of a magnitude in a range from about 1 nm to about 5 nm.

In Example 11, the solid assembly of any one of Examples 1-10 can optionally include the localized charges of the second polarity arranged within the dielectric layer with a defined average charge density in a range from about 10¹² cm⁻² to about 10¹³ cm⁻².

In Example 12, the solid assembly of any one of examples 1-11 can optionally include the carrier-doped semiconductor layer comprising a doped III-V semiconductor compound, and wherein the dielectric layer comprises point defects having respective electronic states of energy greater than a conduction band minimum of the III-V compound.

In Example 13, the solid assembly of any of Examples 1-12 can optionally include the III-V semiconductor compound selected from the group comprising InAs, GaAs, InP, GaP, InSb, AlAs, GaSb, a first alloy of InAs and GaAs, a second alloy of InAl and AlAs, a third alloy of GaAs and AlAs, a fourth alloy of GaAs and GaSb, and a fifth alloy of InAs and InSb, and wherein the dielectric layer is selected from the group comprising Al-rich aluminum oxide and N-deficient silicon nitride.

In Example 14, the solid assembly of any of Examples 1-13 can optionally include the III-V semiconductor compound selected from the group comprising InAs, GaAs, InP, GaP, InSb, AlAs, GaSb, a first alloy of InAs and GaAs, a second alloy of InAl and AlAs, a third alloy of GaAs and AlAs, a fourth alloy of GaAs and GaSb, and a fifth alloy of InAs and InSb, and wherein the dielectric layer is selected form the group comprising La-rich lanthanum oxide, O-rich aluminum oxide, and N-rich silicon nitride.

Example 15 is a method of fabricating a solid-state device, comprising: providing a substrate including a carrier-doped semiconductor layer including mobile charges of a first polarity; providing a dielectric layer including localized charges of a second polarity opposite the first polarity; providing an electrode member adjacent to the dielectric layer and further adjacent to the carrier-doped semiconductor layer.

In Example 16, the method of Example 15 can optionally include providing the carrier-doped semiconductor layer comprising providing a PMOS layer comprising a III-V semiconductor compound doped n-type.

In Example 17, the method of any one of Examples 15-16 can optionally include providing the carrier-doped semiconductor layer comprising providing a PMOS layer comprising a III-V semiconductor compound doped n-type.

In Example 18, the method of any one of Examples 15-17 can optionally include providing the dielectric layer comprising forming a sacrificial member on a surface of the carrier-doped semiconductor layer, the sacrificial member extending from the surface to a distal end along a direction substantially perpendicular to the surface.

In Example 19, the method of any one of Examples 15-18 can optionally include providing the dielectric layer further comprising forming a conformal dielectric layer on the sacrificial member and the surface of the carrier-doped semiconductor layer, resulting in a coated sacrificial member.

In Example 20, the method of any of Examples 15-19 can optionally include forming the conformal dielectric layer comprising depositing an amount of a low-K dielectric material having a first conduction band minimum (CBM) energy greater than a second CBM energy of a semiconductor compound forming the carrier-doped semiconductor layer.

In Example 21, the method of any of Examples 15-20 can optionally include depositing comprising subjecting the sacrificial member and the surface of the carrier-doped semiconductor layer to chemical vapor deposition (CVD) or atomic layer deposition (ALD) of the amount of the low-K dielectric material, wherein the depositing further comprises maintaining, during deposition within a reactor, a first partial pressure of cation-precursor species above a second partial pressure of anion-precursor species.

In Example 22, the method of any of Examples 15-21 can optionally include the depositing further comprising injecting negatively-charged hydrogen atoms into the reactor during deposition, resulting in a second amount of negatively-charged hydrogen atoms being incorporated into the amount of low-K dielectric material.

In Example 23, the method of any of Examples 15-22 can optionally include annealing the conformal dielectric layer at a defined temperature during a time interval to remove at least a portion of the second amount of negatively-charged hydrogen atoms.

In Example 24, the method of any one of Examples 15-23 can optionally include the forming the conformal dielectric layer comprising depositing an amount of a low-K dielectric material having a first valence band maximum (VBM) energy less than a second VBM energy of a semiconductor compound forming the carrier-doped semiconductor layer.

In Example 25, the method of any one of Examples 15-24 can optionally include the depositing comprising subjecting the sacrificial member and the surface of the carrier-doped semiconductor layer to chemical vapor deposition (CVD) or atomic layer deposition (ALD) of the amount of the low-K dielectric material, wherein the depositing further comprises maintaining, during deposition within a reactor, a first partial pressure of anion-precursor species above a second partial pressure of cation-precursor species.

In Example 26, the method of any one of Examples 15-25 can optionally include the depositing further comprising injecting positively-charged hydrogen atoms into the reactor during deposition, resulting in a second amount of positively-charged hydrogen atoms being incorporated into the amount of low-K dielectric material.

In Example 27, the method of any one of examples 15-26 can optionally include annealing the dielectric layer at a defined temperature during a time interval to remove at least a portion of the second amount of positively-charged hydrogen atoms.

In Example 28, the method of any one of examples 15-27 can optionally include the providing the dielectric layer further comprising forming a first spacer layer and a second spacer layer on a portion of the conformal dielectric layer, the first spacer layer adjoining a first sidewall of the coated sacrificial member and the second spacer layer adjoining a second sidewall of the coated sacrificial member, the second sidewall being opposite to the first sidewall.

In Example 29, the method of any one of Examples 15-28 can optionally include the providing the dielectric layer further comprising removing a second portion of the conformal layer.

In Example 30, the method of any one of Examples 15-29 can optionally include the providing the dielectric layer further comprising removing an end portion of the coated sacrificial member opposite the surface of the carrier-doped semiconductor layer.

In Example 31, the method of any one of examples 15-30 can optionally include the providing the dielectric layer further comprising removing the sacrificial member, resulting in an opening exposing a portion of the surface of the carrier-doped semiconductor layer.

In Example 32, the method of any one of Examples 15-31 can optionally include providing the electrode member comprising forming a high-K dielectric layer arranged as a lining in the opening, resulting in a second opening, and filling the second opening with a conductive material.

Example 33 is a solid-state device, comprising: a substrate comprising a p-type metal-oxide-semiconductor (PMOS) layer and an n-type MOS (NMOS) layer; a first dielectric layer adjacent to the PMOS layer and including first localized charges of negative polarity; a first gate electrode adjacent to the first dielectric layer and further adjacent to the substrate; a second dielectric layer adjacent to the NMOS layer and including a second localized charges of positive polarity; and a second gate electrode adjacent to the second dielectric layer and further adjacent to the substrate.

In Example 34, the solid-state device of Example 33 can optionally include the PMOS layer comprising a III-V semiconductor compound doped p-type, and wherein NMOS layer comprises a III-V semiconductor compound doped n-type.

In Example 35, the solid-state device of any one of Examples 33-34 can optionally include the first dielectric layer comprising a first low-K material selected from the group comprising a first oxide, a first nitride, a first carbide, and a first silicate.

In Example 36, the solid-state device of any one of Examples 33-35 can optionally include the second dielectric layer comprising a second low-K material selected from the group comprising a second oxide, a second nitride, a second carbide, and a second silicate.

In Example 37, the solid-state device of any one of Examples 33-36 can optionally include the first dielectric layer having a substantially uniform first thickness of a first magnitude in a range from about 1 nm to about 5 nm.

In Example 38, the solid-state device of any one of Examples 33-37 can optionally include the second dielectric layer having a substantially uniform thickness of a magnitude in the range from about 1 nm to about 5 nm.

In Example 39, the solid-state device of any one of Examples 33-38 can optionally include the first localized charges of negative polarity arranged within the first dielectric layer with a defined average charge density in a range from about 10¹² cm⁻² to about 10¹⁴ cm⁻².

In Example 40, the solid-state device of any one of Examples 33-39 can optionally include the second localized charges of positive polarity arranged within the second dielectric layer with a defined average charge density in a range from about 10¹² cm⁻² to about 10¹⁴ cm⁻².

Example 41 is an electronic device, comprising: at least one semiconductor die having circuitry assembled therein, the circuitry comprising a plurality of solid-state devices, at least one of the plurality of solid-state devices comprising, a carrier-doped semiconductor layer including mobile charges of a first polarity; a dielectric layer including localized charges of a second polarity opposite the first polarity; an electrode member adjacent to the dielectric layer and further adjacent to the carrier-doped semiconductor layer.

In Example 42, the electronic device of Example 41 can optionally include comprising a second carrier-doped semiconductor layer including mobile charges of the second polarity; a second dielectric layer including second localized charges of the first polarity; a second electrode member adjacent to the second dielectric layer and further adjacent to the second carrier-doped semiconductor layer.

In Example 43, the electronic device of any one of Examples 41-42 can optionally include the carrier-doped semiconductor layer comprising a III-V semiconductor compound doped n-type, and wherein the second polarity is positive polarity.

In Example 44, the electronic device of any one of Examples 41-43 can optionally include the carrier-doped semiconductor layer comprising a III-V semiconductor compound doped p-type, and wherein the second polarity is negative polarity.

In Example 45, the electronic device of any one of Examples 41-44 can optionally include the dielectric layer comprising a low-K material selected from the group comprising an oxide, a nitride, a carbide, and a silicate.

In Example 46, the electronic device of any one of Examples 41-45 can optionally include the oxide comprising beryllium oxide, magnesium oxide, aluminum oxide, hafnium oxide, zirconium oxide, lanthanum oxide, yttrium oxide, scandium oxide, or gadolinium oxide.

In Example 47, the electronic device of any one of Examples 41-46 can optionally include the nitride comprising boron nitride, aluminum nitride, or silicon nitride.

In Example 48, the electronic device of any one of Examples 41-47 can optionally include the carbide comprising a wide-bandgap polytype of silicon carbide.

In Example 49, the electronic device of any one of examples 41-48 can optionally include the silicate comprising hafnium silicate or zirconium silicate.

In Example 50, the electronic device of any one of examples 41-48 can optionally include the dielectric layer having a substantially uniform thickness of a magnitude in a range from about 1 nm to about 5 nm.

In Example 51, the electronic device of any one of Examples 41-50 can optionally include the localized charges of the second polarity arranged within the dielectric layer with a defined average charge density in a range from about 10¹² cm⁻² to about 10¹³ cm⁻².

In Example 52, the electronic device of any one of Examples 41-51 can optionally include the carrier-doped semiconductor layer comprising a doped III-V semiconductor compound, and wherein the dielectric layer comprises point defects having respective electronic states of energy greater than a conduction band minimum of the III-V compound.

In Example 53, the electronic device of any one of Examples 41-52 can optionally include the III-V semiconductor compound selected from the group comprising InAs, GaAs, InP, GaP, InSb, AlAs, GaSb, a first alloy of InAs and GaAs, a second alloy of InAl and AlAs, a third alloy of GaAs and AlAs, a fourth alloy of GaAs and GaSb, and a fifth alloy of InAs and InSb, and wherein the dielectric layer is selected from the group comprising Al-rich aluminum oxide and N-deficient silicon nitride.

In Example 54, the electronic device of any one of Examples 41-53 can optionally include the III-V semiconductor compound selected from the group comprising InAs, GaAs, InP, GaP, InSb, AlAs, GaSb, a first alloy of InAs and GaAs, a second alloy of InAl and AlAs, a third alloy of GaAs and AlAs, a fourth alloy of GaAs and GaSb, and a fifth alloy of InAs and InSb, and wherein the dielectric layer is selected form the group comprising La-rich lanthanum oxide, O-rich aluminum oxide, and N-rich silicon nitride.

As mentioned, unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps or it is not otherwise specifically recited in the claims or descriptions of the subject disclosure that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification or annexed drawings, or the like.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language generally is not intended to imply that features, elements, and/or operations are in any way required for one or more implementations or that one or more implementations necessarily include logic for deciding, with or without user input or prompting, whether these features, elements, and/or operations are included or are to be performed in any particular implementation.

As used herein, the term “substantially” indicates that each of the described dimensions is not a strict boundary or parameter and does not exclude functionally similar variations therefrom. Unless context or the description indicates otherwise, the use of the term “substantially” in connection with a numerical parameter indicates that the numerical parameter includes variations that, using mathematical and industrial principles accepted in the art (e.g., rounding, measurement or other systematic errors, manufacturing tolerances, etc.), would not vary the least significant digit.

Further, certain relationships between dimensions of layers of a semiconductor device in accordance with this disclosure and between other elements of the semiconductor device are described herein using the term “substantially equal.” As used herein, the term “substantially equal” indicates that the equal relationship is not a strict relationship and does not exclude functionally similar variations therefrom. Unless context or the description indicates otherwise, the use of the term “substantially equal” in connection with two or more described dimensions indicates that the equal relationship between the dimensions includes variations that, using mathematical and industrial principles accepted in the art (e.g., rounding, measurement or other systematic errors, manufacturing tolerances, etc.), would not vary the least significant digit of the dimensions. As used herein, the term “substantially constant” indicates that the constant relationship is not a strict relationship and does not exclude functionally similar variations therefrom.

As used herein, the term “substantially parallel” indicates that the parallel relationship is not a strict relationship and does not exclude functionally similar variations therefrom. As used herein the term “substantially perpendicular” indicates that the perpendicular relationship between two or more elements of a semiconductor device in accordance with this disclosure are not a strict relationship and does not exclude functionally similar variations therefrom.

The term “horizontal” as used herein may be defined as a direction parallel to a plane or surface (e.g., surface of a substrate), regardless of its orientation. The term “vertical,” as used herein, may refer to a direction orthogonal to the horizontal direction as just described. Terms, such as “on,” “above,” “below,” “bottom,” “top,” “side” (as in “sidewall”), “higher,” “lower,” “upper,” “over,” and “under,” may be referenced with respect to the horizontal plane. The term “processing” as used herein is generally intended to include deposition of material or photoresist, patterning, exposure, development, etching, cleaning, ablating, polishing, and/or removal of the material or photoresist as required in forming a described structure.

What has been described herein in the present specification and annexed drawings includes examples of solid-state assemblies that can embody or otherwise can constitute CMOS transistors and processes for fabricating such solid-state assemblies. It is, of course, not possible to describe every conceivable combination of elements and/or methodologies for purposes of describing the various features of the disclosure, but one of ordinary skill in the art can recognize that many further combinations and permutations of the claimed subject matter are possible. Accordingly, it may be apparent that various modifications can be made to the disclosure without departing from the scope or spirit thereof. In addition or in the alternative, other embodiments of the disclosure may be apparent from consideration of the specification and annexed drawings, and practice of the disclosure as presented herein. It is intended that the examples put forward in the specification and annexed drawings be considered, in all respects, as illustrative and not restrictive. Although specific terms are employed herein, they are used in a generic and descriptive sense only and not for purposes of limitation.

1-25. (canceled)

26. A solid assembly, comprising:
a carrier-doped semiconductor layer including mobile charges of a first polarity;
a dielectric layer including localized charges of a second polarity opposite the first polarity; and
an electrode member adjacent to the dielectric layer and further adjacent to the carrier-doped semiconductor layer.

27. The solid assembly of claim 26, wherein the carrier-doped semiconductor layer comprises an n-type III-V semiconductor compound, and wherein the second polarity is positive polarity.

28. The solid assembly of claim 26, wherein the carrier-doped semiconductor layer comprises a p-type III-V semiconductor compound, and wherein the second polarity is negative polarity.

29. The solid assembly of claim 26, wherein the dielectric layer comprises a low-K material comprising oxygen, nitrogen, carbon, or silicon.

30. The solid assembly of claim 26, wherein the localized charges of the second polarity are arranged within the dielectric layer to an average charge density in a range of 10¹² cm⁻² to 10¹³ cm².

31. The solid assembly of claim 26, wherein the carrier-doped semiconductor layer comprises a doped III-V semiconductor compound, and wherein the dielectric layer comprises point defects having respective electronic states of energy greater than a conduction band minimum of the doped III-V semiconductor compound.

32. The solid assembly of claim 28, wherein the III-V semiconductor compound comprises any of In and As, Ga and As, In and P, Ga and P, In and Sb, Al and As, Ga and Sb, a first alloy of In, Ga and As, a second alloy of In, Al and As, a third alloy of Ga, As and Al, a fourth alloy of Ga, As and Sb, and a fifth alloy of In, As and Sb, and wherein the dielectric layer comprises Al-rich aluminum oxide or N-deficient silicon nitride.

33. The solid assembly of claim 28, wherein the III-V semiconductor compound comprises any of In and As, Ga and As, In and P, Ga and P, In and Sb, Al and As, Ga and Sb, a first alloy of In, Ga and As, a second alloy of In, Al and As, a third alloy of Ga, As and Al, a fourth alloy of Ga, As and Sb, and a fifth alloy of In, As and Sb, and wherein the dielectric layer comprises La-rich lanthanum oxide, O-rich aluminum oxide, or N-rich silicon nitride.

34. A method of fabricating a solid-state device, comprising:
providing a substrate including a carrier-doped semiconductor layer including mobile charges of a first polarity;
providing a dielectric layer including localized charges of a second polarity opposite the first polarity; and
providing an electrode member adjacent to the dielectric layer and further adjacent to the carrier-doped semiconductor layer.

35. The method of claim 34, wherein providing the dielectric layer comprises forming a sacrificial member on a surface of the carrier-doped semiconductor layer, the sacrificial member extending from the surface to a distal end along a direction substantially perpendicular to the surface.

36. The method of claim 35, wherein providing the dielectric layer further comprises forming a conformal dielectric layer on the sacrificial member and the surface of the carrier-doped semiconductor layer, resulting in a coated sacrificial member.

37. The method of claim 36, wherein forming the conformal dielectric layer comprises depositing an amount of a low-K dielectric material having a first conduction band minimum (CBM) energy greater than a second CBM energy of a semiconductor compound forming the carrier-doped semiconductor layer.

38. The method of claim 37, wherein depositing comprises subjecting the sacrificial member and the surface of the carrier-doped semiconductor layer to chemical vapor deposition (CVD) or atomic layer deposition (ALD) of the amount of the low-K dielectric material,
wherein the depositing further comprises maintaining, during deposition within a reactor, a first partial pressure of cation-precursor species above a second partial pressure of anion-precursor species.

39. The method of claim 38, wherein depositing further comprises injecting negatively-charged hydrogen atoms into the reactor during deposition, resulting in a second amount of negatively-charged hydrogen atoms being incorporated into the amount of the low-K dielectric material.

40. The method of claim 36, wherein forming the conformal dielectric layer comprises depositing an amount of a low-K dielectric material having a first valence band maximum (VBM) energy less than a second VBM energy of a semiconductor compound forming the carrier-doped semiconductor layer.

41. The method of claim 40, wherein depositing comprises subjecting the sacrificial member and the surface of the carrier-doped semiconductor layer to chemical vapor deposition (CVD) or atomic layer deposition (ALD) of the amount of the low-K dielectric material,
wherein the depositing further comprises maintaining, during deposition within a reactor, a first partial pressure of anion-precursor species above a second partial pressure of cation-precursor species.

42. The method of claim 41, wherein depositing further comprises injecting positively-charged hydrogen atoms into the reactor during deposition, resulting in a second amount of positively-charged hydrogen atoms being incorporated into the amount of the low-K dielectric material.

43. The method of claim 36, wherein providing the dielectric layer further comprises forming a first spacer layer and a second spacer layer on a portion of the conformal dielectric layer, the first spacer layer adjoining a first sidewall of the coated sacrificial member and the second spacer layer adjoining a second sidewall of the coated sacrificial member, the second sidewall being opposite to the first sidewall.

44. The method of claim 43, wherein providing the dielectric layer further comprises removing a second portion of the conformal dielectric layer.

45. The method of claim 44, wherein providing the dielectric layer further comprises removing an end portion of the coated sacrificial member opposite the surface of the carrier-doped semiconductor layer.

46. The method of claim 45, wherein providing the dielectric layer further comprises removing the sacrificial member, resulting in an opening exposing a portion of the surface of the carrier-doped semiconductor layer.

47. The method of claim 46, providing electrode member comprises forming a high-K dielectric layer arranged as a lining in the opening, resulting in a second opening, and filling the second opening with a conductive material.

48. A solid-state device, comprising:
a substrate comprising a p-type metal-oxide-semiconductor (PMOS) layer and an n-type metal-oxide-semiconductor (NMOS) layer;
a first dielectric layer adjacent to the PMOS layer and including first localized charges of negative polarity;
a first gate electrode adjacent to the first dielectric layer and further adjacent to the substrate;
a second dielectric layer adjacent to the NMOS layer and including second localized charges of positive polarity; and
a second gate electrode adjacent to the second dielectric layer and further adjacent to the substrate.

49. The solid-state device of claim 48, wherein the first dielectric layer comprises a first low-K material selected from a group comprising a first oxide, a first nitride, a first carbide, and a first silicate.

50. The solid-state device of claim 48, wherein the second dielectric layer comprises a second low-K material selected from a group comprising a second oxide, a second nitride, a second carbide, and a second silicate.
